(19) United States
(12) Patent Application Publication
(10) Pub. No.: US 2026/0259100 A1
(43) Pub. Date: Sep. 3, 2026

(54) FLUID LEAKAGE DETECTION

(71) Applicant: Aivres Systems Inc., San Jose, CA (US)

(72) Inventor: Yu Cheng LAI, New Taipei City (TW)

(21) Appl. No.: 19/068,712

(22) Filed: Mar. 3, 2025

(51) Int. Cl. G01M 3/18; G01R 27/22

(52) U.S. Cl. CPC G01M 3/182; G01R 27/22

(57) ABSTRACT

Systems, devices, and methods for detecting fluid leakage are described. In one aspect, a circuit board is configured to generate a leakage detection signal based on an impedance of a leakage sensor. The circuit board includes a transistor, where the transistor includes a first terminal, a second terminal, and a third terminal. The leakage sensor includes a first node and a second node, where the first terminal of the transistor is connected to the first node of the leakage sensor, the second terminal of the transistor is connected to the second node of the leakage sensor. The transistor is configured to detect the impedance between the first node and the second node of the leakage sensor via the first terminal and the second terminal, and generate the leakage detection signal via the third terminal based on the impedance.

### TECHNICAL FIELD

The present disclosure generally relates to systems and methods for detecting fluid leakage, particularly in fluid-cooled systems used for cooling electronic circuits.

### BACKGROUND

As server computing demands continue to grow, traditional fan-based cooling is no longer sufficient, making liquid cooling technology increasingly prevalent. Liquid cooling can utilize sealed coolant-filled lines to dissipate heat from server components. While highly effective in managing heat, coolant leakage presents a serious risk, as the cooling lines run through active server hardware, potentially causing significant damage if leaks occur.

### SUMMARY

The present disclosure describes methods and systems for detecting fluid leakage in fluid-cooled systems.

In a general aspect, a circuit board is configured to generate a leakage detection signal based on an impedance of a leakage sensor. The circuit board includes a transistor. The transistor includes a first terminal, a second terminal, and a third terminal. The leakage sensor includes a first node and a second node. The first terminal of the transistor is connected to the first node of the leakage sensor, the second terminal of the transistor is connected to the second node of the leakage sensor. The transistor is configured to detect the impedance between the first node and the second node of the leakage sensor via the first terminal and the second terminal, and generate the leakage detection signal via the third terminal based on the impedance.

Particular implementations may include one or more of the following features.

In some implementations, the transistor is a bipolar junction transistor (BJT) including a base, a collector, and an emitter. The first terminal is the base of the BJT, the second terminal is the collector of the BJT, and the third terminal is the emitter of the BJT.

In some implementations, the transistor is a N-channel metal-oxide-semiconductor (NMOS) transistor including a gate, a drain, and a source. The first terminal is the gate of the NMOS transistor, the second terminal is the drain of the NMOS transistor, and the third terminal is the source of the NMOS transistor.

In some implementations, the circuit board further includes: a first resistor connected between the first terminal of the transistor and the first node of the leakage sensor, a second resistor connected between the second terminal of the transistor and the second node of the leakage sensor, and a third resistor connected between the third terminal of the transistor and a ground potential.

In some implementations, a resistance of the first resistor is identical to a resistance of the second resistor.

In some implementations, one of the first terminal or the second terminal of the transistor is connected to a voltage source.

In some implementations, the transistor is configured to: generate a first leakage detection signal when the impedance is lower than an impedance threshold, where the first leakage detection signal indicates that fluid leakage is detected; and generate a second leakage detection signal when the impedance is equal to or higher than the impedance threshold, where the second leakage detection signal indicates that fluid leakage is not detected.

In some implementations, the first leakage detection signal indicates a first logical state that is higher than a second logical state indicated by the second leakage detection signal.

In another aspect, a leakage detecting system includes a circuit board connected to a leakage sensor. In some implementations, the circuit board in the leakage detecting system is the circuit board as described above. The leakage detecting system further includes a sever management system including one or more memories and one or more processors. The sever management system is connected to the circuit board, and the sever management system is configured to: receive the leakage detection signal from the circuit board; in response to determining that the leakage detection signal is a first leakage detection signal, sending a leakage notification indicating that fluid leakage is detected; and in response to determining that the leakage detection signal is a second leakage signal, determining not to send the leakage notification indicating that fluid leakage is detected.

In yet another aspect, a leakage detecting method is performed by a leakage detecting system. In some implementations, the leakage detecting system performing the leakage detecting method is the leakage detecting system as described above.

The details of one or more implementations of the subject matter of this disclosure are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates an example leakage detection system, in accordance with one or more implementations of the present disclosure.

FIG. 2 illustrates another example leakage detection system, in accordance with one or more implementations of the present disclosure.

FIG. 3 illustrates another example leakage detection system, in accordance with one or more implementations of the present disclosure.

FIG. 4 illustrates another example leakage detection system, in accordance with one or more implementations of the present disclosure.

FIG. 5 illustrates an example computer system, in accordance with one or more implementations of the present disclosure.

FIG. 6 illustrates an example leakage detection method, in accordance with one or more implementations of the present disclosure.

Like reference numbers and designations in the various drawings indicate like elements.

### DETAILED DESCRIPTION

Leakage detection involves identifying and monitoring unintended fluid leaks within a system to maintain operational integrity and prevent potential malfunctions. Leakage detection is applied across various industries, including Heating, Ventilation, and Air Conditioning (HVAC) systems, industrial pipelines, chemical processing, and for fluid-cooled electronic systems.

Different methods can be used for leakage detection, depending on the system and the type of fluid involved. In some implementations, approaches can include sensor-based detection, visual inspection, and chemical indicators. Sensor-based systems may detect variations in pressure, humidity, conductivity, or temperature that indicate the presence of a leak. Some systems incorporate automated monitoring and real-time alerts to facilitate timely response and mitigation.

In fluid-cooled systems, leakage detection helps maintain system functionality by identifying leaks that may affect performance. However, certain challenges exist in implementing leakage detection systems efficiently. Some approaches require specialized detection equipment that must be integrated with management systems through dedicated communication interfaces. This can limit system scalability and flexibility, as modifications may require compatibility with specific detection devices. Additionally, the need for intermediary communication between detection systems and management platforms may introduce delays in response times, which could impact effectiveness of leak mitigation measures.

Addressing these challenges can improve the efficiency of leakage detection systems by enhancing integration capabilities, reducing reliance on proprietary equipment, and improving response times.

The present disclosure describes approaches to addressing the challenges in leakage detection systems. A custom-designed circuit board, such as a printed circuit board (PCB), can be used to generate a leakage detection signal, which is transmitted to a server management system through a physical signal line, allowing for faster response times. An example circuit board in the present disclosure can include a transistor, such as a bipolar junction transistor (BJT), which can be activated or deactivated based on an impedance drop caused by a leakage detection sensor, such as a leakage detection tape, contacting liquid. The impedance change can trigger a high or low potential output signal, notifying the server management system of the detected leakage. The circuit board can include connectors for interfacing with external devices. One or more connectors of the circuit board can be used to connect leakage detection sensors, while one or more connectors can be used for communication with the server management system. The modular design can allow for multiple connectors to be added as needed, supporting scalability across different applications.

The circuit board can be designed to support flexible signal transmission methods, providing direct integration with the server management system. By utilizing a physical signal cable connection, the circuit board can facilitate faster response times compared to solutions that rely on intermediary detection devices. The compatibility of the circuit board with widely used interfaces, such as an inter-integrated circuit (I2C) interface, can facilitate efficient communication with system management and control functions, reducing the need for additional interface converters. The compact design of the circuit board can allow it to be deployed within a server or a server rack without requiring significant modifications to the existing hardware layout. In some implementations, the circuit board can be configured as a Peripheral Component Interconnect Express (PCIe) card, providing a standardized interface that supports a broad range of server models. This design not only simplifies integration but also enhances the adaptability of the leakage detection system across different server architectures.

When a leak is detected, the server management system can notify the user and take appropriate actions, such as shutting down affected components or securing data to prevent loss. The direct transmission of the leakage detection signal to the server management system can enable a faster response time compared to systems that rely on intermediary detection hardware. The circuit board can be designed to interface directly with the server management system, reducing the need for additional detection equipment. Reducing reliance on additional detection equipment lowers procurement costs, streamlines system integration, and decreases maintenance expenses, making the leakage detection system more cost-effective. The modular architecture of the circuit board allows for flexible hardware configurations, providing adaptation to various applications. Additionally, the low power consumption of the circuit board can support energy-efficient operation. These combined features provide an effective leakage detection solution by improving response speed, reducing costs, and maintaining compatibility with different system architectures.

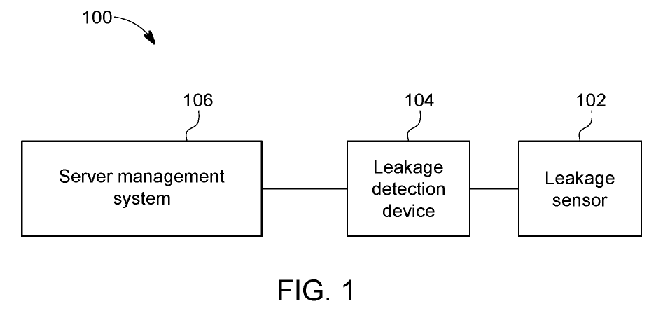

FIG. 1 illustrates an example leakage detection system 100, in accordance with one or more implementations of the present disclosure. In some implementations, the leakage detection system 100 is configured to detect and respond to fluid leaks in a server environment. As illustrated, the system 100 comprises a leakage sensor 102, a leakage detection device 104, and a server management system 106.

In some implementations, the leakage sensor 102 is configured to detect the presence of liquid. The leakage sensor 102 can be implemented in various forms, including leakage detection tape, probes, or other moisture-sensitive elements. In some implementations, the leakage sensor 102 is integrated directly into the leakage detection device 104, forming a single unit.

In some implementations, the leakage sensor 102 is configured to monitor changes in electrical properties, such as impedance or conductivity, which occur when liquid comes into contact with its sensing surface. In some implementations, the leakage sensor 102 includes at least two conductive traces, electrodes, or wires embedded within the sensing structure. These conductive traces, electrodes, or wires can be made from materials such as copper, aluminum, or conductive polymer coatings, serve as detection points. In examples where the leakage sensor 102 is implemented as a leak detection tape, the leakage sensor 102 can include conductive traces that run along the tape and are partially exposed at specific points to allow liquid contact. In examples where the leakage sensor 102 is implemented as a probe-type sensor, the leakage sensor 102 can include metal electrodes that are spaced apart to detect the presence of liquid between them.

In some implementations, an insulating layer or protective coating is applied to the leakage sensor 102 to protect the sensor 102 from environmental interference and unintended activation. This insulating material can be composed of flexible polymer films, silicone coatings, or dielectric layers, depending on the application requirements. The insulation can prevent accidental short circuits while still permitting liquid to reach the conductive traces when a leak occurs. In some implementations, the leakage sensor 102 also includes a moisture-absorbing layer that spreads liquid across a larger surface area, improving response time and increasing the likelihood of detection, particularly for small leaks.

In some implementations, the leakage sensor 102 includes an integrated impedance monitoring circuit designed to continuously track impedance changes between the conductive traces. The traces, electrodes, or wires circuit can consist of passive components, such as resistors and capacitors, or an active microcontroller-based sensing module that generates an output signal when a predefined impedance threshold is reached. This impedance measurement can provide a reliable method for detecting fluid presence, as the electrical properties of the sensor change when exposed to liquid. For example, if the leakage sensor 102 is implemented as a leakage detection tape, the presence of liquid creates a conductive path between two embedded wires, leading to a measurable drop in impedance.

In some implementations, the leakage sensor 102 includes electrical terminals or connectors that link it to the leakage detection device 104. These connectors can take the form of standard twisted-pair wires, terminal blocks, or proprietary connector interfaces, depending on the intended application. In some implementations, the leakage sensor 102 include modular connectors that allow multiple sensors to be connected in series to monitor a wider area.

During operation, the conductive traces in the leakage sensor 102 can remain electrically isolated under normal conditions, maintaining a predefined impedance level. When liquid comes into contact with the exposed conductive traces, a conductive path is created between them, resulting in a measurable drop in impedance. This change can be detected by the leakage detection device 104, which generates and transmits a leakage detection signal to the server management system 106.

In some implementations, the leakage detection device 104 is configured to receive and process raw sensor data from the leakage sensor 102 and generate leakage detection signals. The raw data received from the sensor can vary in signal strength, noise level, and format. The leakage detection device 104 can convert the raw sensor data into a format that can be interpreted by the server management system 106. This conversion process can involve signal amplification to enhance weak signals, noise filtering to eliminate interference from surrounding electronic components, and voltage or data format adjustments to align with the input requirements of the server management system 106. For example, if the leakage sensor 102 generates a low-voltage analog signal, the leakage detection device 104 can amplify it to a higher voltage level or convert it into a digital format for direct processing by the server management system.

In some implementations, the leakage detection device 104 includes signal processing capabilities to differentiate between minor moisture levels and significant leaks. This differentiation can prevent false alarms and ensure that relevant leakage events trigger a system response. For example, the leakage detection device 104 can analyze the duration and intensity of the detected signal to determine whether the detected moisture is due to condensation, a minor spill, or a substantial fluid leak. If the signal indicates a brief and weak moisture presence, it can be classified as condensation and disregarded. However, if the signal persists or rapidly intensifies, the system can classify it as a leak and generate an appropriate alert. In some implementations, the leakage detection device 104 can track signal variations over time, enabling it to recognize progressive leakage conditions. For example, a slow but steady decrease in impedance over an extended period may indicate an accumulating leak, prompting the system to issue an early warning before a critical failure occurs.

In some implementations, the leakage detection device 104 measures the impedance of the leakage sensor 102 and generates a leakage detection signal based on the detected impedance. For example, if the leakage sensor 102 consists of conductive wires embedded within a leak detection tape, the presence of liquid can create a conductive path between the wires, reducing impedance. The leakage detection device 104 can continuously monitor these impedance variations and generate a corresponding leakage detection signal when the measured impedance falls below a predefined threshold. Setting specific impedance thresholds can allow the system to distinguish between normal operating conditions and actual leakage events, improving detection accuracy and reducing unnecessary alerts.

In some implementations, the leakage detection device 104 outputs a logical low signal (e.g., “0”) when the measured impedance remains equal to or above the defined threshold, indicating no leakage. If the impedance drops below the threshold, the leakage detection device 104 outputs a logical high signal (e.g., “1”), signaling the presence of liquid. This binary output can simplify the integration of the leakage detection system with digital processing units in the server management system 106.

In some implementations, when a leakage detection signal is generated, the leakage detection device 104 transmits it to the server management system 106 for further processing. The transmission can be performed through a physical signal line or via a designated communication protocol such as the inter-integrated circuit (I2C) protocol for efficient data exchange between hardware components. Upon receiving the signal, the server management system 106 can initiate appropriate response actions based on predefined parameters. These actions can include notifying system administrators, shutting down affected hardware components to prevent damage, or activating automated mitigation procedures such as redirecting cooling fluid flow to an alternative path. By directly interfacing with the server management system 106, the leakage detection device 104 can provide a timely and appropriate response to leakage events, mitigating potential damage and maintaining system reliability.

In some implementations, the server management system 106 is configured to receive leakage detection signals from the leakage detection device 104 and process the signals to determine an appropriate response. The server management system 106 can continuously monitor incoming signals to assess whether a leakage event has occurred and, if necessary, initiate corrective actions. For example, upon detecting a leak, the server management system 106 can notify users, log the incident for record-keeping and analysis, and implement protective measures to mitigate potential damage. These measures can include shutting down affected hardware components to prevent short circuits, triggering backup processes to safeguard critical data, or adjusting cooling system operations to contain the leak.

In some examples, if the leakage detection device 104 transmits a leakage detection signal indicating that fluid has been detected, the server management system 106 can generate a leakage notification and transmit it to designated personnel or system monitoring interfaces. This notification can be sent as an alert to a centralized server monitoring dashboard, an email to system administrators, or an automated message to a networked maintenance system. In some examples, the server management system 106 can escalate the alert based on the severity of the detected leak. If the signal indicates a minor presence of moisture, the server management system 106 can issue a warning for further inspection. However, if the signal suggests a significant fluid leak (i.e., a major presence of moisture), the server management system 106 can immediately initiate a shutdown sequence, including powering off and closing valves, to prevent damage to critical components.

If the server management system 106 receives a leakage detection signal indicating that no leakage has been detected, the server management system 106 can determine that no action is necessary and refrain from sending a leakage notification. In some examples, if no leakage is detected, the server management system 106 can continuously poll the leakage status and display “OK” on a user interface and take no action until a leak occurs.

In some implementations, the server management system 106 can periodically log the absence of leaks as part of its routine monitoring records, allowing operators to review historical data and confirm that the cooling system remains in proper working condition. By continuously evaluating the signals received from the leakage detection device 104, the server management system 106 can ensure that appropriate responses are executed in a timely manner, mitigating the risk of damage while reducing false alarms and unnecessary system disruptions.

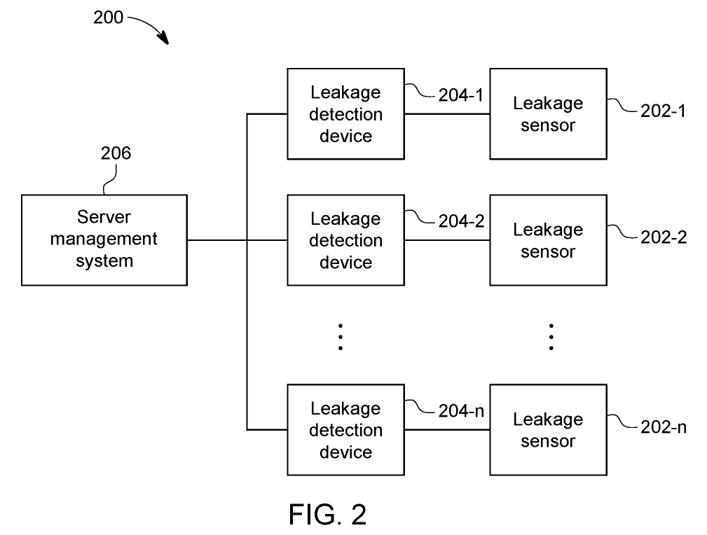

FIG. 2 illustrates another example leakage detection system 200, in accordance with one or more implementations of the present disclosure. In some implementations, the leakage detection system 200 is configured to detect and respond to fluid leaks in a server environment. The system 200 includes multiple leakage sensors 202-1, 202-2, ... 202-n (collectively referred to as 202), leakage detection devices 204-1, 204-2, ... 204-n (collectively referred to as 204), and a server management system 206. Each leakage detection device 204 is paired with a corresponding leakage sensor 202, providing distributed leak detection across multiple locations. In some implementations, the leakage sensors 202 function similarly to the leakage sensor 102, the leakage detection devices 204 operate in a manner similar to the leakage detection device 104, and the server management system 206 performs functions similar to the server management system 106. To avoid redundancy, certain details regarding the components of the system 200 have been omitted.

In some implementations, the leakage detection system 200 is configured to monitor multiple locations within the server environment, improving coverage and responsiveness compared to a single-sensor system. Each leakage detection device 204 is connected to a corresponding leakage sensor 202, allowing the system 200 to monitor for leaks across different areas independently. In operation, each leakage sensor 202 functions similarly to the leakage sensor 102 in system 100, and each leakage sensor 202 detects the presence of liquid by monitoring changes in electrical properties such as impedance or conductivity. The leakage sensor 202 can be implemented as leak detection tapes, probes, or other moisture-sensitive elements placed within the server environment, such as beneath cooling lines, near server racks, or along pathways where leaks are likely to occur.

Each leakage detection device 204 can be configured to process data from its respective leakage sensor 202. When a leakage sensor 202 detects liquid, the impedance of the leakage sensor changes, and the leakage detection device 204 converts the impedance into a leakage detection signal. Since multiple leakage detection devices 204 can operate in parallel, the leakage detection devices 204 can independently monitor different locations, allowing leaks in separate areas to be detected promptly.

When a leakage detection device 204 generates a leakage detection signal, the leakage detection device 204 can transmit the signal to the server management system 206. The server management system 206 acts as the central controller, collecting signals from multiple leakage detection devices 204 and determining the appropriate response based on predefined conditions. In some examples, if a single sensor 202 detects a minor leak, the server management system 206 can generate an early warning notification to alert administrators. If multiple sensors 202 report leaks in different locations or a sensor detects a significant drop in impedance indicative of a major leak, the server management system 206 can escalate the response by triggering hardware shutdowns, activating backup cooling measures, or logging the event for maintenance records.

For example, if a leakage sensor 202-1 positioned beneath a cooling pipe detects moisture, the leakage detection device 204-1 processes the signal and transmits an alert to the server management system 206. The server management system 206 can send a warning notification to an administrator, prompting an inspection. If, simultaneously, leakage sensor 202-2 in another location also detects a leak, the server management system 206 can recognize a broader failure pattern and initiate a more immediate response, such as shutting down affected cooling units, servers, or other equipment to prevent further leakage or damage.

By incorporating multiple leakage sensors 202 and detection devices 204, the leakage detection system 200 can improve fault tolerance and scalability. The modular design can allow additional sensors and detection devices to be integrated as needed, making the system adaptable to different server environments and risk levels. The distributed architecture allows each monitored area to operate independently while still reporting to a central system, enabling localized detection with a coordinated response.

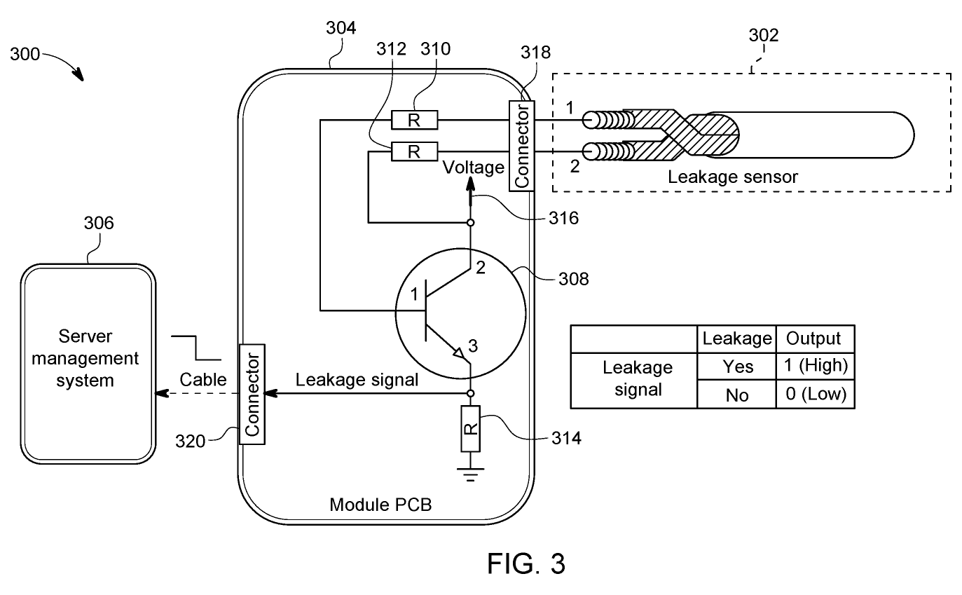

FIG. 3 illustrates another example leakage detection system 300, in accordance with one or more implementations of the present disclosure. In some implementations, the leakage detection system 300 is configured to detect and respond to fluid leaks in a server environment. The system 300 includes a leakage sensor 302, a leakage detection device 304, and a server management system 306. In some implementations, the leakage sensor 302 functions similarly to the leakage sensors 102 and 202, the leakage detection device 304 operates in a manner similar to the leakage detection devices 104 and 204, and the server management system 306 performs functions similar to the server management systems 106 and 206. To avoid redundancy, certain details regarding the components of the system 300 have been omitted.

In some implementations, the leakage sensor 302 is configured with two conductive wires embedded within its sensing structure. These conductive wires function as detection points and can be made from materials such as copper, aluminum, or conductive polymer coatings, which provide good electrical conductivity and durability. The leakage sensor 302 includes two nodes, labeled as “1” and “2”, located at the ends of the conductive wires. These nodes serve as connection points for interfacing with the leakage detection device 304 or other monitoring components.

To protect the sensor 302 from external interference and unintended activation, an insulating layer is applied over the conductive wires. This insulation helps prevent accidental short circuits while still allowing liquid to reach the conductive traces when a leak occurs. The insulating material can be composed of flexible polymer films, silicone coatings, or dielectric layers, depending on the specific application requirements. For example, in environments where the sensor is exposed to varying temperatures and humidity, a silicone-based insulating layer can be used due to its flexibility and resistance to environmental degradation. In industrial or data center settings, a dielectric coating can be used for its electrical insulating properties and long-term stability.

The insulating layer is configured to leave the end portions of the conductive wires, including the two nodes, exposed. This configuration allows for direct electrical contact with the leakage detection device, facilitating accurate signal transmission when a leak is detected. The exposed end portions of the conductive wires can allow any liquid entering the detection area to create a conductive path between the wires, altering the impedance and triggering a response from the monitoring system.

The leakage sensor 302 is further enclosed within an outer protective layer to provide additional durability and resistance to mechanical damage. In some examples, the outer protective layer can be made from materials such as nylon. This protective layer can shield the internal components from physical wear, moisture buildup, and potential contaminants that could affect the sensor 302’s performance. For example, in a data center environment where sensors may be placed under server racks or along cooling lines, the nylon outer layer prevents damage from dust, accidental contact, or movement of nearby components.

In some implementations, the leakage detection device 304 is implemented as a circuit board, such as a printed circuit board (PCB), and is configured to process signals from the leakage sensor 302 to determine whether a fluid leak is present. In the example of FIG. 3, the leakage detection device 304 includes a transistor 308, which can be configured to detect changes in impedance caused by fluid contact with the leakage sensor 302. The transistor 308 has three terminals, labeled as first terminal (“1”), second terminal (“2”), and third terminal (“3”). In operation, the first terminal can be used to control conductivity or current flow between the second terminal and the third terminal, depending on the signal received at the first terminal. The transistor 308 can monitor impedance between the first and second nodes of the leakage sensor 302 and generate a leakage detection signal at the third terminal based on the detected impedance.

In the example of FIG. 3, the transistor 308 is implemented as a bipolar junction transistor (BJT), which consists of a base, collector, and emitter. In this configuration, the base corresponds to the first terminal, the collector corresponds to the second terminal, and the emitter corresponds to the third terminal. The leakage detection device 304 is electrically connected to the leakage sensor 302, where the first terminal of the transistor 308 is connected to the first node of the leakage sensor 302, and the second terminal is connected to the second node. It should be noted that the transistor 308 is not restricted to being a BJT and can be implemented using any suitable transistor or component, such as N-channel metal-oxide-semiconductor (NMOS) transistor.

The leakage detection device 304 further includes resistors that form part of the detection circuitry to regulate signal flow. A first resistor 310 is connected between the first terminal of the transistor 308 and the first node of the leakage sensor 302. A second resistor 312 is positioned between the second node of the leakage sensor 302 and the second terminal of the transistor 308. A third resistor 314 is connected between the third terminal of the transistor 308 and a ground potential. The resistances of these resistors can be selected based on application requirements. In some examples, the first resistor 310 and second resistor 312 have equal resistance values, such as 100 ohms, while the third resistor 314 has a resistance of 1,000 ohms. However, these values are only examples, and the resistance of each component can be adjusted depending on the specific configuration and sensitivity requirements of the leakage detection system.

The leakage detection device 304 is powered by a voltage source 316, which supplies the operating voltage to the circuit. In some implementations, the voltage source 316 provides a voltage ranging from 5 to 12 volts. The power source can be implemented in different ways depending on the system configuration. In some implementations, the voltage source 316 is an integrated battery within the leakage detection device 304, allowing the device 304 to function independently. In some implementations, the server management system 306 supplies the voltage source 316 through a cable connecting the leakage detection device 304 to the server management system 306, removing the need for a separate power source and allowing for centralized power management.

During operation, the transistor 308 can generate leakage detection signals based on the impedance measured between the two nodes of the leakage sensor 302. When the measured impedance falls below a predefined impedance threshold, indicating that liquid has created a conductive path between the sensor nodes, the transistor 308 can generate a first leakage detection signal, which signifies that a fluid leak has been detected. If the impedance remains equal to or higher than the threshold, the transistor 308 can generate a second leakage detection signal, indicating that no fluid leakage is present.

In some implementations, the leakage detection signals are represented as logical states. In some examples, the first leakage detection signal can be assigned a first logical state (e.g., “1”), which corresponds to a detected leakage condition. The second leakage detection signal can be assigned a second logical state (e.g., “0”), which represents a no-leakage condition. These logical signals can be transmitted to the server management system 306, allowing it to take appropriate actions, such as issuing an alert, logging the incident, or initiating protective measures like shutting down affected hardware.

The leakage detection device 304 further includes a first connector 318 and a second connector 320, which facilitate communication between the leakage detection device 304 and other system components. The first connector 318 is configured to establish an electrical connection between the leakage detection device 304 and the leakage sensor 302, enabling the detection device 304 to receive signals related to fluid leakage. The second connector 320 serves as the interface between the leakage detection device 304 and the server management system 306, allowing for the transmission of processed leakage detection signals to the management system.

The configuration and type of connectors 318 and 320 used in the system can vary depending on specific application requirements. In some examples, the first connector 318 can be a terminal block, a screw-type connector, or a custom plug to accommodate different types of leakage sensors, such as leak detection tape or probe-type sensors. The selection of the connector can depend on factors such as the type of sensor, the environmental conditions where the sensor is deployed, and the required level of signal stability. For example, in environments with high vibrations or mechanical movement, a secure locking connector may be preferred to prevent accidental disconnections.

The second connector 320 can be chosen based on the communication requirements between the leakage detection device 304 and the server management system 306. In some implementations, the second connector 320 can be implemented as a PCIe connector, allowing the leakage detection device 304 to interface directly with the server management system 306 as an expansion card. This PCIe configuration can provide high-speed data transmission, reduce latency, and integrate seamlessly with modern server architectures. In some examples, the second connector 320 can be a standard I2C interface, a USB connector, or an Ethernet port, depending on the communication protocol for the server management system 306.

For example, if the server management system 306 operates in a data center environment, a PCIe-based leakage detection device can be installed directly onto a motherboard or an expansion slot, allowing the system to continuously monitor for fluid leakage without additional external wiring. As another example, if the system is used in an industrial setting where remote monitoring is required, an Ethernet-enabled connector can be preferable, enabling the leakage detection signals to be transmitted over a network to a centralized monitoring system.

The customizable nature of the first connector 318 and second connector 320 can provide flexibility in adapting the leakage detection device 304 to various deployment scenarios. This adaptability can allow the system to be integrated into different hardware configurations while ensuring reliable and secure data transmission between the sensor, detection device, and server management system.

By integrating a transistor-based impedance measurement system with a structured resistor network and a configurable power source, the leakage detection device 304 can provide an efficient and scalable approach to fluid leak detection. The ability to differentiate between leakage and no-leakage conditions using well-defined impedance thresholds can facilitate accurate detection while reducing false alarms.

Additionally, the customizable nature of the connectors can improve the adaptability of the leakage detection device 304 across different deployment scenarios. The ability to configure the first connector 318 to support various types of leakage sensors 302, such as leak detection tapes or probe-based sensors, allows the system to be tailored for different environments, ranging from data centers to industrial facilities. Similarly, the second connector 320 can be adjusted to support multiple communication protocols, such as PCIe, I2C, USB, or Ethernet, enabling seamless integration with diverse server management systems 306. This flexibility not only improves ease of installation but also makes the system compatible with a wide range of hardware configurations, reducing the need for specialized equipment.

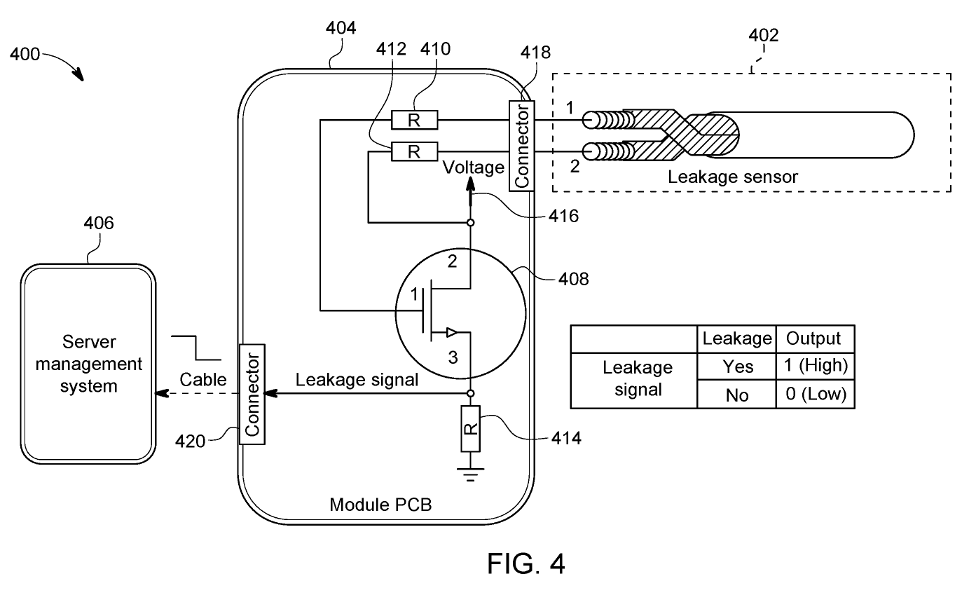

FIG. 4 illustrates another leakage detection system 400, in accordance with one or more implementations of the present disclosure. The system 400 includes a leakage sensor 402, a leakage detection device 404, and a server management system 406, each functioning similarly to their counterparts in previous implementations as described with reference to FIGS. 1-3. In some implementations, the leakage sensor 402 is configured to detect fluid presence by monitoring changes in electrical properties, such as impedance or conductivity. The leakage detection device 404 can be configured to process signals received from the leakage sensor 402 and generate a leakage detection signal that is transmitted to the server management system 406. The server management system 406 can be configured to evaluate the received signal and determine the appropriate response, such as issuing an alert, logging the event, or initiating protective measures. To avoid redundancy, certain details regarding the components of system 400 have been omitted.

The leakage detection device 404 includes a transistor 408; resistors 410, 412, and 414; connectors 418 and 420; and a voltage source 416. The resistor 410 is connected between the first terminal (labeled as “1”) of the transistor 408 and the first node (labeled as “1”) of the leakage sensor 402, while the resistor 412 is connected between the second terminal (label as “2”) of the transistor 408 and the second node (labeled as “2”) of the leakage sensor 402. The resistor 414 is connected between the third terminal (labeled as “3”) of the transistor 408 and a ground potential, providing a reference point for circuit stability.

The voltage source 416 is configured to supply power to the leakage detection device 404 and can be implemented in different ways depending on the system configuration. In some implementations, the voltage source 416 is an integrated power supply, such as a battery or a dedicated voltage regulator embedded within the leakage detection device 404. In some implementations, the server management system 406 provides the voltage via a power cable, allowing centralized power management and reducing the need for an independent power source within the detection device. For example, in a large-scale data center, supplying power directly from the server management system 406 can simplify maintenance and streamline power distribution.

In system 400, the transistor 408 is implemented as an NMOS transistor. The NMOS transistor includes three terminals: a gate, a drain, and a source. In this configuration, the first terminal of the transistor 408 corresponds to the gate, the second terminal corresponds to the drain, and the third terminal corresponds to the source. The leakage detection device 404 is connected to the leakage sensor 402, where the first terminal (gate) is connected to the first node of the leakage sensor 402, and the second terminal (drain) is connected to the second node of the leakage sensor 402.

During operation, when the leakage sensor 402 detects fluid, its impedance changes, affecting the voltage at the gate terminal of the transistor 408. This voltage change influences the current flow between the drain and source, allowing the leakage detection device 404 to generate a corresponding leakage detection signal. The server management system 406 receives this signal and determines whether further action is required, such as notifying system administrators, logging the event, or initiating protective measures like shutting down affected components.

The leakage detection system 400 can support various deployment configurations, with flexible options for power sourcing, signal transmission, and sensor placement. By integrating an NMOS transistor-based detection circuit, the system provides a structured and scalable approach for real-time leakage monitoring in server environments, allowing for effective leak detection and response.

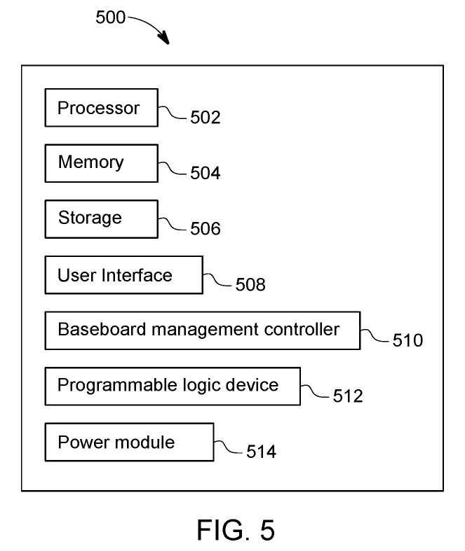

FIG. 5 is a diagram illustrating an example computer system 500, in accordance with one or more implementations of the present disclosure. The computer system 500 can be implemented as one or more of the server management systems 106, 206, 306, or 406 described in previous implementations. In some implementations, the computer system 500 is configured to manage, process, and respond to leakage detection signals received from a leakage detection device, coordinating appropriate system actions based on detected fluid leakage conditions.

The computer system 500 includes one or more processors 502 that can be configured to execute software programs, manage system resources, and coordinate the overall operation of the system. The processors 502 can be implemented as single-core or multi-core architectures, depending on the computing power required for system management tasks. The one or more memories 504 can provide storage for actively running programs and processes. For example, the one or more memories 504 can be random-access memory (RAM) modules that store data for quick access by the processors 502. The one or more storages 506 can provide non-volatile storage solutions for long-term data retention. These storage devices 506 can be implemented as solid-state drives (SSDs), hard disk drives (HDDs), or other persistent storage media. The storages 506 can be used to log leakage detection events, store historical system data, and maintain system configuration files for future reference.

The user interface 508 provides an interface through which administrators or system operators can interact with the computer system 500. The user interface 508 can include one or more of a graphical user interface (GUI) displayed on a monitor, a command-line interface (CLI) accessed via a remote terminal, or a network-based management portal. The user interface 508 can allow operators to view system alerts, configure leakage detection settings, and manage responses to leakage events.

The baseboard management controller 510 can be a hardware component configured to oversee system functions related to monitoring and control. In some examples, the baseboard management controller 510 can be configured to receive leakage detection signals from a leakage detection device, interpret the received signals, and trigger appropriate alerts when fluid leakage is detected. For example, if the baseboard management controller 510 receives a signal indicating fluid presence, it can generate an alert displayed on the user interface 508, send an automated notification to system administrators, or log the incident for further analysis.

The programmable logic device 512, such as a complex programmable logic device (CPLD), is included to perform real-time system operations in response to leakage detection events. The programmable logic device 512 can be programmed to execute automated responses such as initiating a controlled system shutdown, activating backup power, or transferring critical data to a secure storage location in the event of a detected leak. The ability to customize the logic-based response mechanisms can provide flexibility in adapting to various operational requirements.

The power module 514 is configured to supply electrical power to the components of the computer system 500 and can include power regulation circuits, backup power sources, or uninterruptible power supply (UPS) integration.

In an example operation, the computer system 500 can continuously monitor input signals from the leakage detection device through the baseboard management controller 510. When a leakage detection signal is received, the baseboard management controller 510 can determine the appropriate system response, which can involve triggering alerts, activating protective measures, or logging the event for later review. The programmable logic device 512 can execute additional actions such as shutting down affected hardware, securing sensitive data, or managing power distribution to prevent damage.

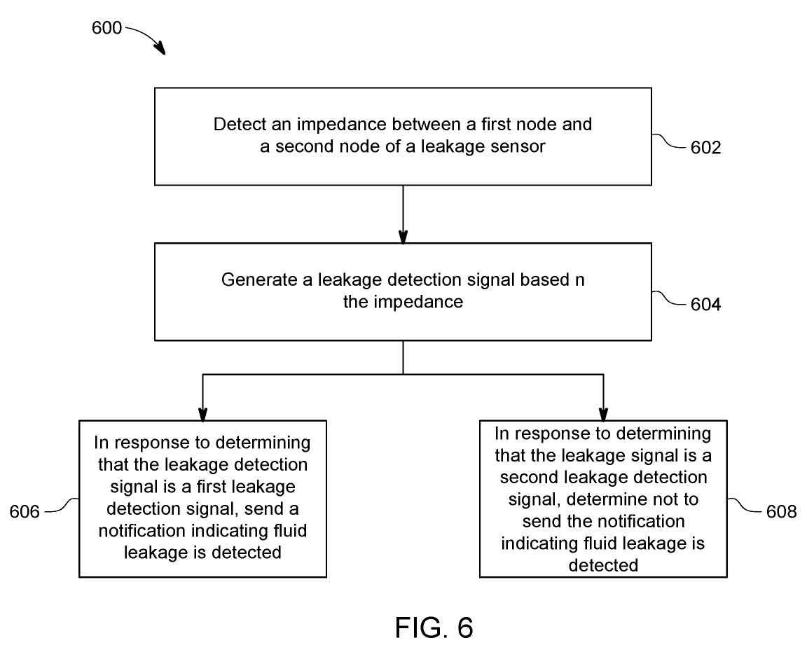

FIG. 6 is a flow chart illustrating an example leakage detection method 600, in accordance with one or more implementations of the present disclosure. The method 600 can be performed by one or more of the systems 100, 200, 300, 400, or 500. For illustrative purposes, the method 600 is explained in relation to the leakage detection system 300 as described below.

An impedance is detected between a first node and a second node of a leakage sensor (602). In some implementations, a leakage detection device, such as the leakage detection device 304, is configured to detect the impedance across a leakage sensor, such as the leakage sensor 302. The leakage detection device 304 includes a transistor 308, which has a first terminal, a second terminal, and a third terminal. The leakage detection device 304 is connected to the leakage sensor 302, where the first terminal of the transistor 308 is connected to a first node of the leakage sensor 302, and the second terminal of the transistor 308 is connected to a second node of the leakage sensor 302.

The impedance can be detected based on the electrical properties of the leakage sensor 302, which change when liquid comes into contact with the sensor. 302 For example, if the leakage sensor 302 is implemented as a leak detection tape, the presence of fluid bridges the conductive traces within the tape, lowering the impedance. When no fluid is present, the impedance remains high. The leakage detection device 304 can continuously monitor this impedance to determine whether a leakage condition exists.

A leakage detection signal is generated based on the impedance (604). In some examples, the leakage detection signal can be generated by the transistor 308 via the third terminal of the transistor 308, which serves as an output based on the measured impedance. When the impedance between the first node and second node of the leakage sensor 302 falls below a predefined threshold, indicating the presence of fluid, the transistor 308 changes its conductivity state, allowing current to pass through and generating a leakage detection signal.

This signal can be a logical high (“1”) or logical low (“0”) output, depending on the configuration. For example, when the impedance drops below the defined threshold, meaning that fluid is detected, the transistor 308 can output a logical high (“1”) signal, representing a leakage condition. When the impedance remains equal to or above the threshold, indicating no fluid presence, the transistor 308 can output a logical low (“0”) signal, signifying that no leakage has been detected.

The leakage detection device 304 can then transmit the leakage detection signal to the server management system 306 for further processing.

In response to determining that the leakage detection signal is a first leakage detection signal, a leakage notification is sent, indicating that fluid leakage has been detected (606). For example, the server management system 306 can evaluate the received leakage detection signal and determine if the leakage detection signal meets a predefined criteria for a leak condition. In some examples, the server management system 306 can detect leakage when it receives a logical high (“1”) signal, indicating that the measured impedance has fallen below a set threshold due to fluid presence.

Once determining that leakage is detected, the system 306 can generate a leakage notification, which can take different forms depending on the implementation. For example, the server management system 306 can display a warning on a monitoring dashboard, send an email or text alert to administrators, or trigger an alarm within a data center environment.

The system 306 can further log the leakage event for future reference and initiate automated protective measures, such as shutting down affected components to prevent hardware damage.

In response to determining that the leakage detection signal is a second leakage detection signal, it can be determined that a leakage notification will not be sent (608). For example, this can occur when the measured impedance remains equal to or above the defined threshold, indicating that no fluid is present at the leakage sensor 302. In such cases, the leakage detection device 304 can generate a signal representing a no-leak condition, which can be a logical low (“0”) signal. The server management system 306 can determine that the leakage notification should not be sent after receiving the signal indicating the no-leak condition. While no leakage notification is sent, the system can still log the no-leak status as part of routine monitoring and diagnostic records.

By implementing these steps, the leakage detection method 600 can provide a structured approach to detecting and responding to fluid leaks. The method 600 can provide real-time monitoring, minimize false alarms, and allow the server management system 306 to take appropriate actions based on actual leakage conditions.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual’s action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application specific integrated circuit (ASIC). In some implementations, the computer or computer-implemented system or special-purpose logic circuitry (or a combination of the computer or computer-implemented system and special-purpose logic circuitry) can be hardware- or software-based (or a combination of both hardware- and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a standalone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer readable media for storing computer program instructions and data can include all forms of permanent/non-permanent or volatile/non-volatile memory, media and memory devices, including by way of example semiconductor memory devices, for example, random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto optical disks; and optical memory devices, for example, digital versatile/video disc (DVD), compact disc (CD) ROM, DVD+/-R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user’s mobile computing device in response to requests received from the web browser).

The term “graphical user interface (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back end, middleware, or front end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation may be applicable to a computer-implemented method; a non-transitory, computer-readable medium storing computer-readable instructions to perform the computer-implemented method; and/or a computer system comprising a computer memory interoperably coupled with a hardware processor configured to perform the computer-implemented method or the instructions stored on the non-transitory, computer-readable medium.

What is claimed is:

1. A circuit board, wherein the circuit board is configured to generate a leakage detection signal based on an impedance of a leakage sensor, and the circuit board comprises:
a transistor, wherein the transistor comprises a first terminal, a second terminal, and a third terminal, wherein the leakage sensor comprises a first node and a second node, wherein the first terminal of the transistor is connected to the first node of the leakage sensor, the second terminal of the transistor is connected to the second node of the leakage sensor, wherein the transistor is configured to detect the impedance between the first node and the second node of the leakage sensor via the first terminal and the second terminal, and generate the leakage detection signal via the third terminal based on the impedance.

2. The circuit board according to claim 1, wherein the transistor is a bipolar junction transistor (BJT) comprising a base, a collector, and an emitter, and wherein the first terminal is the base of the BJT, the second terminal is the collector of the BJT, and the third terminal is the emitter of the BJT.

3. The circuit board according to claim 1, wherein the transistor is a N-channel metal-oxide-semiconductor (NMOS) transistor, comprising a gate, a drain, and a source, and wherein the first terminal is the gate of the NMOS transistor, the second terminal is the drain of the NMOS transistor, and the third terminal is the source of the NMOS transistor.

4. The circuit board according to claim 1, further comprising:
a first resistor connected between the first terminal of the transistor and the first node of the leakage sensor;
a second resistor connected between the second terminal of the transistor and the second node of the leakage sensor; and
a third resistor connected between the third terminal of the transistor and a ground potential.

5. The circuit board according to claim 4, wherein a resistance of the first resistor is identical to a resistance of the second resistor.

6. The circuit board according to claim 1, wherein one of the first terminal or the second terminal of the transistor is connected to a voltage source.

7. The circuit board according to claim 1, wherein the transistor is configured to:
generate a first leakage detection signal when the impedance is lower than an impedance threshold, wherein the first leakage detection signal indicates that fluid leakage is detected; and
generate a second leakage detection signal when the impedance is equal to or higher than the impedance threshold, wherein the second leakage detection signal indicates that fluid leakage is not detected.

8. The circuit board according to claim 7, wherein the first leakage detection signal indicates a first logical state that is higher than a second logical state indicated by the second leakage detection signal.

9. A leakage detecting system, comprising:
a circuit board connected to a leakage sensor, wherein the circuit board is configured to generate a leakage detection signal based on an impedance of the leakage sensor, and the circuit board comprises:
a transistor, wherein the transistor comprises a first terminal, a second terminal, and a third terminal, wherein the leakage sensor comprises a first node and a second node, wherein the first terminal of the transistor is connected to the first node of the leakage sensor, the second terminal of the transistor is connected to the second node of the leakage sensor, wherein the transistor is configured to detect the impedance between the first node and the second node of the leakage sensor via the first terminal and the second terminal, and generate the leakage detection signal via the third terminal based on the impedance; and
a sever management system comprising one or more memories and one or more processors, wherein the sever management system is connected to the circuit board, and the sever management system is configured to:
receive the leakage detection signal from the circuit board;
in response to determining that the leakage detection signal is a first leakage detection signal, sending a leakage notification indicating that fluid leakage is detected; and
in response to determining that the leakage detection signal is a second leakage detection signal, determining not to send the leakage notification indicating that fluid leakage is detected.

10. The leakage detecting system according to claim 9, wherein the first leakage detection signal indicates a first logical state that is higher than a second logical state indicated by the second leakage detection signal.

11. The leakage detecting system according to claim 9, wherein the transistor is a bipolar junction transistor (BJT) comprising a base, a collector, and an emitter, and wherein the first terminal is the base of the BJT, the second terminal is the collector of the BJT, and the third terminal is the emitter of the BJT.

12. The leakage detecting system according to claim 9, wherein the transistor is a N-channel metal-oxide-semiconductor (NMOS) transistor comprising a gate, a drain, and a source, and wherein the first terminal is the gate of the NMOS transistor, the second terminal is the drain of the NMOS transistor, and the third terminal is the source of the NMOS transistor.

13. The leakage detecting system according to claim 9, wherein the circuit board further comprises:
a first resistor connected between the first terminal of the transistor and the first node of the leakage sensor;
a second resistor connected between the second terminal of the transistor and the second node of the leakage sensor; and
a third resistor connected between the third terminal of the transistor and a ground potential.

14. The leakage detecting system according to claim 13, wherein a resistance of the first resistor is identical to a resistance of the second resistor.

15. The leakage detecting system according to claim 9, wherein one of the first terminal or the second terminal of the transistor is connected to a voltage source.

16. The leakage detecting system according to claim 9, the transistor is configured to:
generate the first leakage detection signal when the impedance is lower than an impedance threshold, wherein the first leakage detection signal indicates that fluid leakage is detected; and
generate the second leakage detection signal when the impedance is equal to or higher than the impedance threshold, wherein the second leakage detection signal indicates that fluid leakage is not detected.

17. A leakage detecting method performed by a leakage detecting system, wherein the leakage detecting system comprises a circuit board and a sever management system connected to the circuit board, wherein the circuit board is connected to a leakage sensor and is configured to generate a leakage detection signal based on an impedance of the leakage sensor, wherein the circuit board comprises a transistor, wherein the transistor comprises a first terminal, a second terminal, and a third terminal, wherein the leakage sensor comprises a first node and a second node, wherein the first terminal of the transistor is connected to the first node of the leakage sensor, the second terminal of the transistor is connected to the second node of the leakage sensor, wherein the sever management system comprises one or more memories and one or more processors, and wherein the leakage detecting method comprises:
detecting the impedance between the first node and the second node of the leakage sensor via the first terminal and the second terminal of the transistor;
generating the leakage detection signal via the third terminal of the transistor based on the impedance;
in response to determining that the leakage detection signal is a first leakage detection signal, sending a leakage notification indicating that fluid leakage is detected; and
in response to determining that the leakage detection signal is a second leakage detection signal, determining not to send the leakage notification indicating that fluid leakage is detected.

18. The leakage detecting method according to claim 17, wherein the transistor is a bipolar junction transistor (BJT) comprising a base, a collector, and an emitter, and wherein the first terminal is the base of the BJT, the second terminal is the collector of the BJT, and the third terminal is the emitter of the BJT.

19. The leakage detecting method according to claim 17, wherein the transistor is a N-channel metal-oxide-semiconductor (NMOS) transistor comprising a gate, a drain, and a source, and wherein the first terminal is the gate of the NMOS transistor, the second terminal is the drain of the NMOS transistor, and the third terminal is the source of the NMOS transistor.

20. The leakage detecting method according to claim 17, further comprising:
generating the first leakage detection signal when the impedance is lower than an impedance threshold, wherein the first leakage detection signal indicates that fluid leakage is detected; and
generating the second leakage detection signal when the impedance is equal to or higher than the impedance threshold, wherein the second leakage detection signal indicates that fluid leakage is not detected.
